(19) United States
(12) Patent Application Publication
(10) Pub. No.: US 2018/0358206 A1
(43) Pub. Date: Dec. 13, 2018

(54) Plasma Processing Apparatus

(71) Applicant: Mattson Technology, Inc., Fremont, CA (US)

(72) Inventors: Shawming Ma, Sunnyvale, CA (US); Vladimir Nagorny, Tracy, CA (US); Dixit V. Desai, Pleasanton, CA (US); Ryan Pakulski, Discovery Bay, CA (US)

(21) Appl. No.: 15/888,283

(22) Filed: Feb. 5, 2018

Related U.S. Application Data
(60) Provisional application No. 62/610,601, filed on Dec. 27, 2017.
(60) Provisional application No. 62/517,365, filed on Jun. 9, 2017.

(51) Int. Cl. H01J 37/32; G03F 7/42; B08B 5/00

(52) U.S. Cl. CPC H01J 37/32357; H01J 37/32422; B08B 5/00; H01J 37/3244; G03F 7/427; H01J 37/32651

(57) ABSTRACT

Plasma processing apparatus are provided. In one example implementation, a plasma processing apparatus includes a processing chamber. The apparatus includes a pedestal operable to support a workpiece in the processing chamber. The apparatus includes a plasma chamber. The plasma chamber defines an active plasma generation region along a vertical surface of a dielectric sidewall of the plasma chamber. The apparatus includes a separation grid positioned between the processing chamber and the plasma chamber along a vertical direction. The apparatus includes a plurality of induction coils extending about the plasma chamber. Each of the plurality of induction coils can be disposed at a different position along the vertical direction. Each of the plurality of induction coils can be operable to generate a plasma in the active plasma generation region along the vertical surface of the dielectric sidewall of the plasma chamber.

### PRIORITY CLAIM

The present application claims the benefit of priority of U.S. Provisional Patent Application No. 62/610,601, entitled “Plasma Processing Apparatus With Plasma Source Tunability,” filed on Dec. 27, 2017, which is incorporated herein by reference. The present application claims the benefit of priority of U.S. Provisional Patent Application No. 62/517,365, entitled “Plasma Strip Tool with Uniformity Control,” filed on Jun. 9, 2017, which is incorporated herein by reference for all purposes.

### FIELD

The present disclosure relates generally to apparatus, systems, and methods for processing a substrate using a plasma source.

### BACKGROUND

Plasma processing is widely used in the semiconductor industry for deposition, etching, resist removal, and related processing of semiconductor wafers and other substrates. Plasma sources (e.g., microwave, ECR, inductive, etc.) are often used for plasma processing to produce high density plasma and reactive species for processing substrates. Plasma strip tools can be used for strip processes, such as photoresist removal. Plasma strip tools can include a plasma chamber where plasma is generated and a separate processing chamber where the substrate is processed. The processing chamber can be “downstream” of the plasma chamber such that there is no direct exposure of the substrate to the plasma. A separation grid can be used to separate the processing chamber from the plasma chamber. The separation grid can be transparent to neutral species but not transparent to charged particles from the plasma. The separation grid can include a sheet of material with holes.

### SUMMARY

Aspects and advantages of embodiments of the present disclosure will be set forth in part in the following description, or may be learned from the description, or may be learned through practice of the embodiments.

One example aspect of the present disclosure is directed to a plasma processing apparatus. The apparatus includes a processing chamber. The apparatus includes a pedestal operable to support a workpiece in the processing chamber. The apparatus includes a plasma chamber. The plasma chamber can define an active plasma generation region along a vertical surface of a dielectric sidewall of the plasma chamber. The apparatus includes a separation grid positioned between the processing chamber and the plasma chamber along a vertical direction. The apparatus includes a plurality of induction coils about the plasma chamber. Each of the plurality of induction coils is disposed at a different position along the vertical direction. Each of the plurality of induction coils is operable to generate a plasma in the active plasma generation region along the vertical surface of the dielectric sidewall of the plasma chamber.

Another example aspect of the present disclosure is directed to a plasma processing apparatus. The apparatus includes a processing chamber. The apparatus includes a plasma chamber. The plasma chamber includes a dielectric sidewall. The apparatus includes a separation grid position between the processing chamber and the plasma chamber along a vertical direction. The dielectric sidewall includes a first portion and a second portion. The second portion of the dielectric sidewall flares from the firs portion of the dielectric sidewall. The apparatus includes a first induction coil positioned about the first portion of the dielectric sidewall. The apparatus includes a second induction coil positioned adjacent to the second portion of the dielectric sidewall.

Other examples aspects of the present disclosure are directed to apparatus, methods, processes, separation grids, and devices for plasma processing of a workpiece.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example plasma processing tool;

FIG. 2 depicts a portion of an example plasma processing tool according to an example embodiment of the present subject matter;

FIG. 3 depicts a portion of an example plasma processing tool according to an example embodiments of the present disclosure;

FIG. 4 depicts a portion of an example plasma processing tool according to another example embodiment of the present subject matter; and

FIG. 5 depicts a flow diagram of an example method for processing a workpiece according to an example embodiment of the present subject matter.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to plasma processing apparatus, such as plasma strip tools. Example embodiments can be used to provide uniformity tunability in a plasma processing tool using features that can provide for source tunability. Source tunability can refer to the ability to adjust inductive source coil characteristics (e.g., source coil power) for generating a plasma in a plasma chamber to affect uniformity in performing a strip process on a workpiece in a downstream processing chamber.

For instance, in some embodiments, a plurality of source coils can be disposed at different vertical locations about a plasma chamber in a plasma processing tool to provide for upper and lower plasma density tunability in the plasma chamber. For instance, a first source coil can be disposed at a first vertical position and a second source coil can be disposed at a second vertical position. One or more grounded Faraday shields can be disposed between the plurality of source coils and the plasma chamber.

In one example embodiment, the plasma chamber can have a first portion with vertical sidewalls and a second portion with angled sidewalls. The vertical sidewalls and the angled sidewalls can be formed from a dielectric material. The surface of the sidewalls can be covered by a grounded Faraday shield. A first source coil can be disposed about the first portion with vertical sidewalls. A second source coil can be disposed about the second portion with angled sidewalls. This can provide for tuning of, for instance, plasma density at different locations (e.g., center portion versus edge portion) of the plasma chamber.

In one example embodiment, a plasma processing apparatus includes a processing chamber. The apparatus includes a pedestal operable to support a workpiece in the processing chamber. The apparatus includes a plasma chamber. The plasma chamber defines an active plasma generation region along a vertical surface of a dielectric sidewall of the plasma chamber. The apparatus includes a separation grid positioned between the processing chamber and the plasma chamber along a vertical direction. The apparatus includes a plurality of induction coils extending about the plasma chamber. Each of the plurality of induction coils can be disposed at a different position along the vertical direction. Each of the plurality of induction coils can be operable to generate a plasma in the active plasma generation region along the vertical surface of the dielectric sidewall of the plasma chamber.

In some embodiments, the apparatus can include a radio frequency power generator coupled to each of the plurality of induction coils. The radio frequency power generator can be operable to energy one or more of the plurality of induction coils to generate the plasma.

In some embodiments, the plurality of induction coils includes a first induction coil positioned at a first vertical position adjacent the vertical surface of the dielectric sidewall. The apparatus includes a second induction coil positioned at a second vertical position adjacent the vertical surface of the dielectric sidewall. The first induction coil can be coupled to a first radio frequency power generator. The second induction coil can be coupled to a second radio frequency power generator.

In some embodiments, the apparatus can include a gas injection insert disposed within the plasma chamber. At least a portion of the active plasma generation region in the plasma chamber can be defined by the gas injection insert. In some embodiments, the gas injection insert includes a peripheral portion and a center portion. The center portion extends a vertical distance beyond the peripheral portion (e.g., to provide a stepped gas injection insert).

In some embodiments, the separation grid can include a plurality of holes operable to allow passage of neutral particles generated in a plasma to the processing chamber. The separation grid can be operable to filter one or more ions generated in the plasma.

In some embodiments, the apparatus can include a gas injection port operable to inject a process gas adjacent to the vertical surface of the dielectric insert. For instance, the gas injection port can inject a process gas into the plasma chamber in a gas injection channel defined between a gas injection insert and a vertical portion of the dielectric sidewall.

Another example embodiment is directed to a plasma processing apparatus. The apparatus includes a processing chamber. The apparatus can include a plasma chamber. The plasma chamber includes a dielectric sidewall. The apparatus can include a separation grid positioned between the processing chamber and the plasma chamber along a vertical direction. The dielectric sidewall includes a first portion and a second portion. The second portion of the dielectric sidewall can be adjacent to the separation grid. Th second portion can flare from the first portion of the dielectric sidewall. The apparatus includes a first induction coil positioned about the first portion of the dielectric sidewall. The apparatus includes a second induction coil positioned adjacent to the second portion of the dielectric sidewall.

In some embodiments, the plasma chamber has a width along a horizontal direction. The width of the plasma chamber at the second portion of the dielectric sidewall is greater than a width of the plasma chamber at the first portion of the dielectric sidewall.

In some embodiments, the apparatus includes a grounded Faraday shield positioned between the first induction coil and the first portion of the dielectric sidewall and between the second induction coil and the second portion of the dielectric sidewall. In some embodiments, the grounded Faraday shield is a unitary structure. In some embodiments, a density of spaces in the grounded Faraday shield adjacent the first portion of the dielectric sidewall is different than a density of spaces of the grounded Faraday shield adjacent the second portion of the dielectric sidewall.

In some embodiments, the apparatus can include a gas injection insert disposed within the plasma chamber. At least a portion of the active plasma generation region in the plasma chamber can be defined by the gas injection insert. In some embodiments, the gas injection insert includes a peripheral portion and a center portion. The center portion extends a vertical distance beyond the peripheral portion (e.g., to provide a stepped gas injection insert).

In some embodiments, the separation grid can include a plurality of holes operable to allow passage of neutral particles generated in a plasma to the processing chamber. The separation grid can be operable to filter one or more ions generated in the plasma.

In some embodiments, the apparatus can include a gas injection port operable to inject a process gas adjacent to the vertical surface of the dielectric insert. For instance, the gas injection port can inject a process gas into the plasma chamber in a gas injection channel defined between a gas injection insert and a vertical portion of the dielectric sidewall.

Another example embodiments of the present disclosure is directed to a method for processing a workpiece. The method can include placing the workpiece in a processing chamber. The processing chamber is separated from a plasma chamber by a separation grid along a vertical direction. The method can include providing a process gas into the plasma chamber via a gas injection port proximate a vertical surface of a dielectric sidewall. The method can include energizing a first induction coil proximate the vertical surface of the dielectric sidewall with radio frequency energy. The method can include energizing a second induction coil proximate the separation grid with radio frequency energy. The method can include flowing neutral particles generated in a plasma through the separation grid to the workpiece within the processing chamber.

In some embodiments, the second induction coil is located proximate the vertical surface of the dielectric sidewall. For instance, the second induction coil is located proximate the vertical surface of the dielectric sidewall at a vertical position that adjacent to the separation grid.

In some embodiments, the dielectric sidewall can include a first portion and a second portion. The second portion of the dielectric sidewall flaring from the first portion of the dielectric sidewall. The second induction coil is located proximate the second portion of the dielectric sidewall.

Aspects of the present disclosure are discussed with reference to a “wafer” or semiconductor wafer for purposes of illustration and discussion. Those of ordinary skill in the art, using the disclosures provided herein, will understand that the example aspects of the present disclosure can be used in association with any semiconductor substrate or other suitable substrate. In addition, the use of the term “about” in conjunction with a numerical value is intended to refer to within ten percent (10%) of the stated numerical value. A “pedestal” refers to any structure that can be used to support a workpiece.

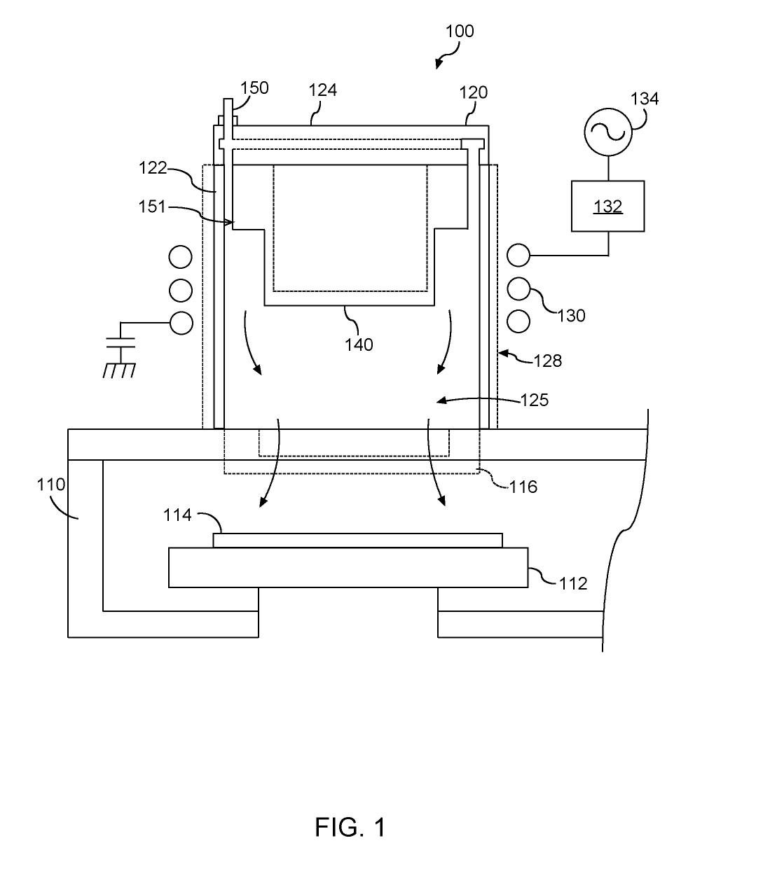

With reference now to the FIGS., example embodiments of the present disclosure will now be set forth. FIG. 1 depicts an example plasma processing tool 100. The processing tool 100 includes a processing chamber 110 and a plasma chamber 120 that is separate from the processing chamber 110. The processing chamber 110 includes a substrate holder or pedestal 112 operable to hold a substrate 114. An inductive plasma can be generated in plasma chamber 120 (i.e., plasma generation region) and desired particles are then channeled from the plasma chamber 120 to the surface of substrate 114 through holes provided in a separation grid 116 that separates the plasma chamber 120 from the processing chamber 110 (i.e., downstream region).

The plasma chamber 120 includes a dielectric sidewall 122. The plasma chamber 120 includes a top plate 124. The dielectric sidewall 122 and ceiling 124 define a plasma chamber interior 125. Dielectric sidewall 122 can be formed from any dielectric material, such as quartz. An induction coil 130 can be disposed adjacent the dielectric sidewall 122 about the plasma chamber 120. The induction coil 130 can be coupled to an RF power generator 134 through a suitable matching network 132. Reactant and carrier gases can be provided to the chamber interior from gas supply 150. When the induction coil 130 is energized with RF power from the RF power generator 134, a substantially inductive plasma is induced in the plasma chamber 120. In a particular embodiment, the plasma processing tool 100 can include a grounded Faraday shield 128 to reduce capacitive coupling of the induction coil 130 to the plasma.

To increase efficiency, the plasma processing tool 100 can include a gas injection insert 140 disposed in the chamber interior 125. The gas injection insert 140 can be removably inserted into the chamber interior 125 or can be a fixed part of the plasma chamber 120. In some embodiments, the gas injection insert can define a gas injection channel 151 proximate the sidewall of the plasma chamber. The gas injection channel can feed the process gas into the chamber interior proximate the induction coil and into an active region defined by the gas injection insert and sidewall. The active region provides a confined region within the plasma chamber interior for active heating of electrons. The narrow gas injection channel prevents plasma spreading from the chamber interior into the gas channel. The gas injection insert forces the process gas to be passed through the active region where electrons are actively heated.

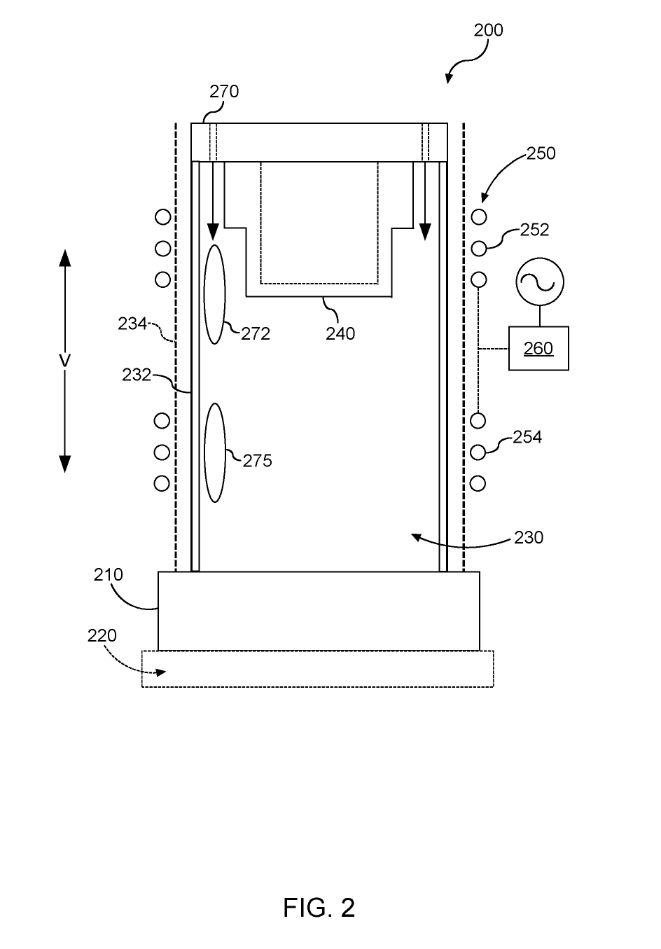

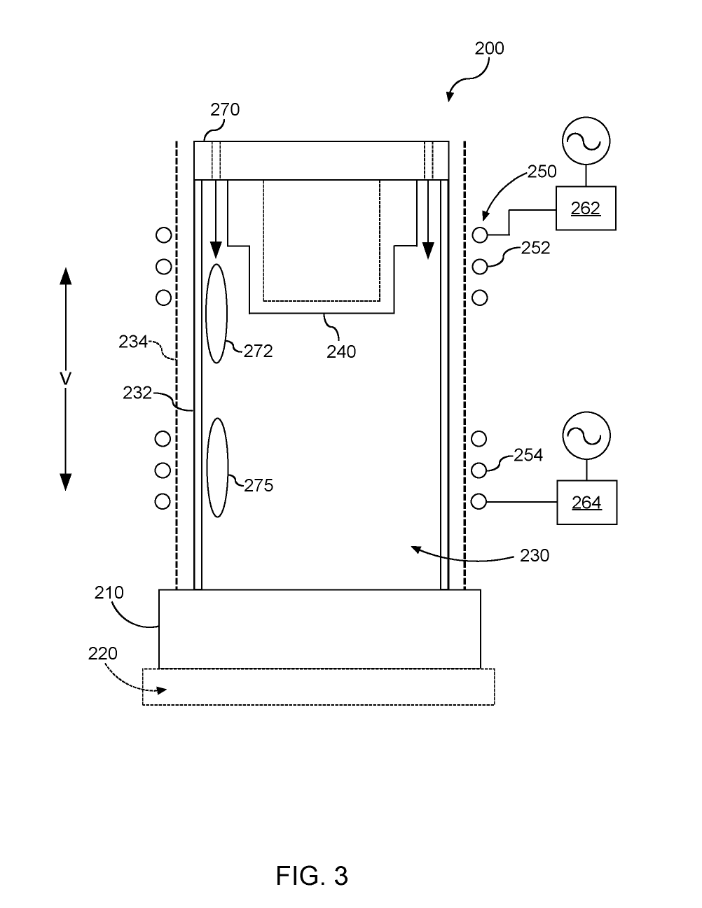

Various features for improving uniformity of a processing tool, such as processing tool 100 will now be set forth with reference to FIGS. 2 and 3.

FIG. 2 depicts components of an example plasma processing tool 200 according to an example embodiment of the present disclosure. Plasma processing tool 200 may be constructed in a similar manner to processing tool 100 (FIG. 1) and operate in the manner described above for processing tool 100. It will be understood that the components of plasma processing tool 200 shown in FIG. 2 may also be incorporated into any other suitable plasma processing tools in alternative example embodiments. As discussed in greater detail below, plasma processing tool 200 includes features for improving source tunability relative to known plasma processing tools.

Plasma processing tool 200 includes a separation grid assembly 210 that is positioned between a processing chamber 220 and a plasma chamber 230 along a vertical direction V. A workpiece may be positioned within the processing chamber 220, and neutral particles from an inductive plasma within plasma chamber 230 may flow through separation grid assembly 210, (e.g., downwardly along the vertical direction V). In the processing chamber 220, the neutral particles may impact against the workpiece in a striping process, e.g., to strip a photoresist layer from the workpiece or to perform other surface treatment processes. Plasma processing tool 200 may also include a gas injection insert 240 in certain example embodiments.

A plurality of induction coils 250 extend about plasma chamber 230, and each induction coil 250 is disposed at a different position along the vertical direction V on plasma chamber 230, e.g., such that induction coils 250 are spaced from each other along the vertical direction V on plasma chamber 230. For example, induction coils 250 may include a first induction coil 252 and a second induction coil 254. First induction coil 252 may be positioned at a first vertical position along a vertical surface of a dielectric sidewall 232. Conversely, second induction coil 254 may be positioned at a second vertical position along a vertical surface of the dielectric sidewall 232. The first vertical position is different from the second vertical position. For instance, the first vertical position may be above the second vertical position.

It will be understood that, while shown with two induction coils 250 in the example embodiment shown in FIG. 2, one or more additional induction coils 250 at different vertical positions may be used without deviating from the scope of the present disclosure. By providing two or more induction coils 250, plasma processing tool 200 need not include gas injection insert 240 in certain example embodiments.

In certain example embodiments, the respective position of each induction coil 250 along the vertical direction V is fixed. Thus, a spacing along the vertical direction V between adjacent induction coils 250 may also be fixed. In alternative example embodiments, one or more of induction coils 250 may be movable along the vertical direction V relative to plasma chamber 230. Thus, e.g., the spacing along the vertical direction V between adjacent induction coils 250 may be adjustable. Adjusting the relative position of an induction coil 250 along the vertical direction V can assist with improving source tunability relative to known plasma processing tools.

Induction coils 250 are operable to generate an inductive plasma within plasma chamber 230. For example, plasma processing tool 200 may include a radio frequency power generator 260 (e.g., RF generator and matching network). Radio frequency power generator 260 is coupled to induction coils 250, and radio frequency power generator 260 is operable to energize induction coils 250 to generate the inductive plasma in plasma chamber 230. In particular, radio frequency power generator 260 may energize induction coils 250 with an alternating current (AC) of radio frequency (RF) such that the AC induces an alternating magnetic field inside induction coils 250 that heats a flow of gas to generate the inductive plasma. In some embodiments, induction coils 250 may be coupled to a single radio frequency power generator 260. Thus, e.g., both first and second induction coils 252, 254 may be coupled to the same radio frequency power generator 260 so that RF power is split among first and second induction coils 252, 254. It will be understood that each of induction coils 250 may be coupled to a respective radio frequency power generator in alternative example embodiments, as discussed in greater detail with respect to FIG. 3 below.

A dielectric sidewall 232 may be positioned between induction coils 250 and plasma chamber 230. Dielectric sidewall 232 may have a generally cylindrical shape. A grounded Faraday shield 234 may also be positioned between induction coils 250 and plasma chamber 230. For example, grounded Faraday shield 234 may be positioned between induction coils 250 and dielectric sidewall 232. Dielectric sidewall 232 may contain the inductive plasma within plasma chamber 230 while allowing the alternating magnetic field from induction coils 250 to pass through to plasma chamber 230, and grounded Faraday shield 234 may reduce capacitive coupling of induction coils 250 to the inductive plasma within plasma chamber 230. In certain example embodiments, a density of spaces in the grounded Faraday shield 234 (e.g., density of shield material relative to holes or spaces) changes along the vertical direction. For example, the density of spaces in the grounded Faraday shield 234 at or adjacent first induction coil 252 may be different than the density of spaces in the grounded Faraday shield 234 at or adjacent second induction coil 254. In particular, the density of spaces in the grounded Faraday shield 234 at or adjacent first induction coil 252 may be more or less than the density of spaces in the grounded Faraday shield 234 at or adjacent second induction coil 254, in certain example embodiments.

As noted above, each induction coil 250 is disposed at a different position along the vertical direction V on plasma chamber 230 adjacent a vertical portion of a dielectric sidewall of the plasma chamber 230. In this way, each induction coil 250 can be operable to generate a plasma in an active plasma generation region along the vertical surface of the dielectric sidewall 232 of the plasma chamber.

More particularly, the plasma processing tool 200 can include a gas injection port 270 operable to inject process gas at the periphery of the plasma chamber 230 along a vertical surface of the dielectric sidewall 232. This can define active plasma generation regions adjacent the vertical surface of the dielectric sidewall 232. For instance, the first induction coil 252 can be operable to generate a plasma in region 272 proximate a vertical surface of the dielectric sidewall 232. The second induction coil 254 can be operable to generate a plasma in region 275 proximate a vertical surface of the dielectric sidewall 232. The gas injection insert 240, in some embodiments, can further define an active region for generation of the plasma in the plasma chamber 230 adjacent the vertical surface of the dielectric sidewall 232.

Plasma processing tool 200 can have improved source tunability relative to known plasma processing tools. For example, providing two or more induction coils 250 along the vertical surface of the dielectric sidewall 232 proximate active plasma generation region in the plasma chamber 230 allows the plasma processing tool 200 to have improved source tunability. In particular, providing a plurality of induction coils 250 in combination with adjusting the density of grounded Faraday shield 234 along the vertical direction V may facilitate tuning of the inductive plasma at various locations along the vertical direction V. In such a manner, a treatment process performed with plasma processing tool 200 on a workpiece may be more uniform

In some embodiments, the induction coil 252 and induction coil 254 may be coupled to independent RF generators. In this way, the RF power applied to each induction coil 252 and induction coil 254 can be independently controlled to tune plasma density in a vertical direction in the plasma chamber 230. FIG. 3 depicts a plasma processing apparatus 200 that is similar to that of FIG. 2 except that the induction coil 252 is coupled to a first RF generator 262 (e.g., RF generator and matching network) and the induction coil 254 is coupled to a second RF generator 264 (e.g., RF generator and matching network). The frequency and/or power of RF energy applied by the first RF generator 262 and the second RF generator 264 to the first induction coil 252 and the second induction coil 254 respectively can be adjusted to be the same or different to control process parameters of a surface treatment process.

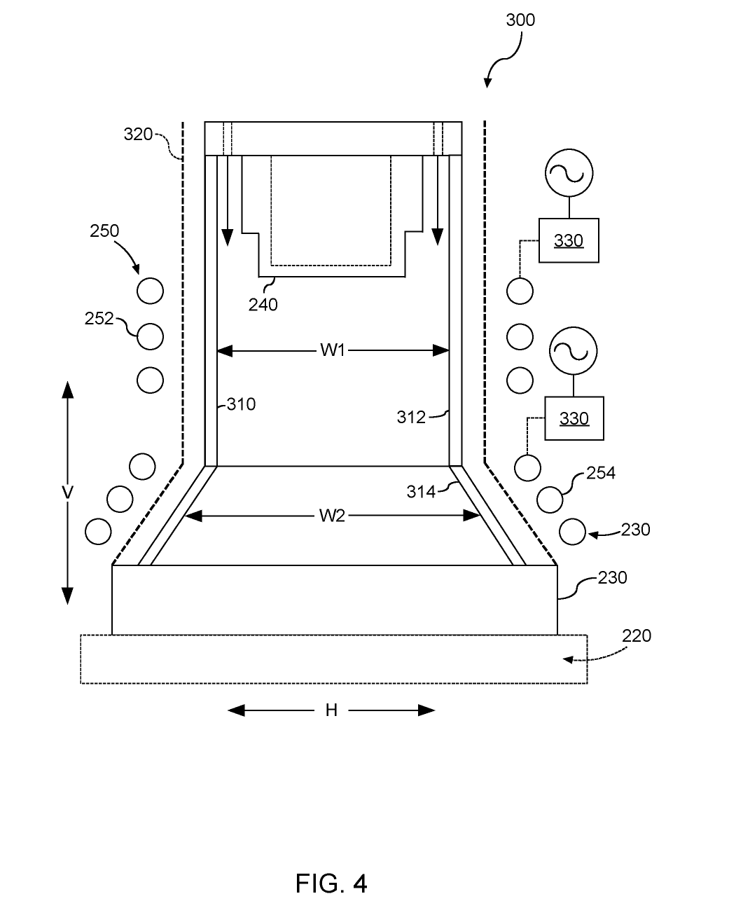

FIG. 4 depicts components of an example plasma processing tool 300 according to another example embodiment of the present disclosure. Plasma processing tool 300 includes numerous common component with plasma processing tool 200 (FIGS. 2, 3). For example, plasma processing tool 300 includes separation grid assembly 210, processing chamber 220, plasma chamber 230 and induction coils 250. Thus, plasma processing tool 300 may also operate in a similar manner to that described above for plasma processing tool 200. It will be understood that the components of plasma processing tool 300 shown in FIG. 3 may also be incorporated into any other suitable plasma processing tool in alternative example embodiments. As discussed in greater detail below, plasma processing tool 300 includes features for improving source tunability relative to known plasma processing tools.

In plasma processing tool 300, a dielectric sidewall 310 is positioned between induction coils 250 and plasma chamber 230. Dielectric sidewall 310 may contain the inductive plasma within plasma chamber 230 while allowing the alternating magnetic field from induction coils 250 to pass through to plasma chamber 230. Dielectric sidewall 310 may be sized and/or shaped to facilitate source tunability.

Dielectric sidewall 310 includes a first portion 312 and a second portion 314. Second portion 314 of dielectric sidewall 310 flares from first portion 312 of dielectric sidewall 310. In certain example embodiments, first portion 312 of dielectric sidewall 310 may be vertically oriented and have a generally cylindrical inner surface that faces plasma chamber 230, and second portion 314 of dielectric sidewall 310 may angled (e.g., not vertical or horizontal) and may have a generally frusto-conical inner surface that faces plasma chamber 230. Thus, e.g., a width of plasma chamber 230 along a horizontal direction H may be greater at second portion 314 of dielectric sidewall 310 than at first portion 312 of dielectric sidewall 310.

In particular, plasma chamber 230 has a first width W1 along the horizontal direction H at first portion 312 of dielectric sidewall 310, and plasma chamber 230 has a second width W2 along the horizontal direction H at second portion 314 of dielectric sidewall 310. The second width W2 is greater than the first width W1. In such a manner, the width of plasma chamber 230 along the horizontal direction H may be greater at or adjacent separation grid assembly 210 relative to the width of plasma chamber 230 along the horizontal direction H opposite the separation grid assembly 210 along the vertical direction V. One of induction coils 250 may be positioned at each of first and second portions 312, 314 of dielectric sidewall 310. In particular, first induction coil 252 may be positioned at first portion 312 of dielectric sidewall 310, and second induction coil 254 may be positioned at second portion 314 of dielectric sidewall 310 proximate separation grid 210.

A grounded Faraday shield 320 may also be positioned between induction coils 250 and plasma chamber 230. For example, grounded Faraday shield 320 may be positioned between induction coils 250 and dielectric sidewall 310. Grounded Faraday shield 320 may reduce capacitive coupling of induction coils 250 to the inductive plasma within plasma chamber 230. Grounded Faraday shield 320 may be a unitary structure. Grounded Faraday shield 320 may be configured (e.g., sized and/or shaped) to facilitate source tunability. For example, a density of of spaces in grounded Faraday shield 320 at first portion 312 of dielectric sidewall 310 may be different than the density of spaces in grounded Faraday shield 320 at second portion 314 of dielectric sidewall 310. In certain example embodiments, the density of spaces in grounded Faraday shield 320 at first portion 312 of dielectric sidewall 310 may be more or less than the density of spaces in grounded Faraday shield 320 at second portion 314 of dielectric sidewall 310. Thus, the density of grounded Faraday shield 320 may vary along the vertical direction V.

As discussed above, induction coils 250 are operable to generate an inductive plasma within plasma chamber 230. In plasma processing tool 300, a plurality of radio frequency power generators 330 (e.g., RF generators and matching networks) is coupled to induction coils 250, and radio frequency power generators 330 are operable to energize induction coils 250 to generate the inductive plasma in plasma chamber 230. In particular, each of radio frequency power generator 330 may energize a respective one of induction coils 250 with an alternating current (AC) of radio frequency (RF) such that the AC induces an alternating magnetic field inside induction coils 250 that heats a flow of gas to generate the inductive plasma. Thus, each of radio frequency power generators 330 may be coupled to an independent radio frequency power generator 330 to provide for independent control of RF power to induction coils 250. Frequency and/or power of RF energy applies using the independent power generators 330 can be adjusted to be the same or different to control process parameters of a surface treatment process.

Plasma processing tool 300 can have improved source tunability. For example, proving a plurality of induction coils 250 in combination with vertical and angled portions on dielectric sidewall 310 allows a user of plasma processing tool 300 to have improved source tunability. As another example, adjusting the density of grounded Faraday shield 320 along the vertical direction V in combination with providing two or more induction coils 250 allows a user of plasma processing tool 300 to have improved source tunability. As yet another example, proving a plurality of induction coils 250 in combination with a plurality of radio frequency power generators 330 allows a user to adjust one or more of the frequency, voltage, power etc, of the RF energy to induction coils 250 to thereby have improved source tunability relative to known plasma processing tools. In such a manner, a plasma processing process performed with plasma processing tool 300 on a workpiece can be controlled to be more uniform.

A method for plasma processing a workpiece with plasma processing tool 200 (FIG. 2) or plasma processing tool 300 (FIG. 4) is described below. At a beginning of the plasma processing process, a workpiece may be placed in processing chamber 220. The user may the activate radio frequency power generators to generate an inductive plasma within plasma chamber 230. From the plasma chamber 230, neutral particles of the inductive plasma flow through separation grid 210 to the workpiece within processing chamber 230. In such a manner, the workpiece in processing chamber 220 may be exposed to neutral particles generated in the inductive plasma that pass through separation grid 210. The neutral particles can be used, for instance, as part of a surface treatment process (e.g., photoresist removal).

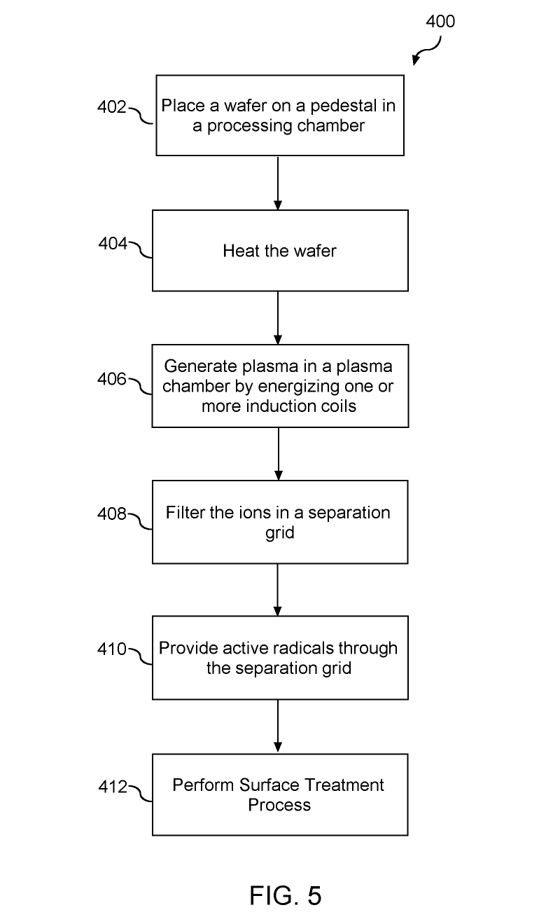

As a particular example, FIG. 5 depicts a flow diagram of an example method 400 according to example embodiments of the present disclosure. The method 400 can be implemented, for instance, using any of the plasma processing apparatus disclosed herein or other suitable plasma processing apparatus. FIG. 4 depicts steps performed in a particular order for purposes of illustration and discussion. Those of ordinary skill in the art, using the disclosures provided herein, will understand that the various steps or operations of any of the methods described herein can be adapted, expanded, include steps not illustrated, performed simultaneously, rearranged, omitted, and/or modified in various ways without deviating from the scope of the present disclosure.

At 402, the method 400 can include placing a wafer on a pedestal in a processing chamber. The semiconductor wafer can then be heated for surface treatment process as shown at 404. For instance, one or more heat sources in a pedestal can be used to heat the semiconductor wafer.

At 406, the method can include generating a plasma in a plasma chamber. The plasma chamber can be remote from the processing chamber. The plasma chamber can be separated from the processing chamber with a separation grid. The plasma can be generated by energizing one or more induction coils proximate the processing chamber with RF energy to generate a plasma using a process gas admitted into the plasma chamber. For instance, process gas can be admitted into the plasma chamber from a gas source. RF energy from RF source(s) can be applied to induction coil(s) to generate a plasma in the plasma chamber.

At 408, the method can include filtering ions generated in the plasma using a the separation grid. As discussed above, the separation grid can include a plurality of holes. The holes can prevent the passage of ions generated in the plasma from passing from the plasma chamber to the processing chamber. The separation grid can also be used to reduce UV light from entering the processing chamber from the plasma chamber.

At 410, the method can include providing active radicals through the separation grid. For instance, the separation grid can include holes that allow for the passage of active radicals (e.g. neutrals) generated in the plasma through the separation grid. At 412, the method can include performing a surface treatment process (e.g., strip process) on the surface of a workpiece using one or more neutral particles passing through the separation grid.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A plasma processing apparatus, comprising:
a processing chamber;
a pedestal operable to support a workpiece in the processing chamber;
a plasma chamber, the plasma chamber defining an active plasma generation region along a vertical surface of a dielectric sidewall of the plasma chamber;
a separation grid positioned between the processing chamber and the plasma chamber along a vertical direction; and
a plurality of induction coils extending about the plasma chamber, each of the plurality of induction coils disposed at a different position along the vertical surface of the dielectric sidewall, each of the plurality of induction coils operable to generate a plasma in the active plasma generation region along the vertical surface of the dielectric sidewall of the plasma chamber.

2. The plasma processing apparatus of claim 1, further comprising a radio frequency power generator coupled to each of the plurality of induction coils, the radio frequency power generator operable to energize one or more of the plurality of induction coils to generate the plasma.

3. The plasma processing apparatus of claim 1, wherein the plurality of induction coils comprises a first induction coil positioned at a first vertical position adjacent the vertical surface of the dielectric sidewall and a second induction coil positioned at a second vertical position adjacent the vertical surface of the dielectric sidewall.

4. The plasma processing apparatus of claim 3, wherein the first induction coil is coupled to a first radio frequency power generator and the second induction coil is coupled to a second radio frequency power generator.

5. The plasma processing apparatus of claim 1, wherein at least a portion of the active plasma generation region in the plasma chamber is defined by a gas injection insert.

6. The plasma processing apparatus of claim 5, wherein the gas injection insert comprises a peripheral portion and a center portion, the center portion extending a vertical distance beyond the peripheral portion.

7. The plasma processing apparatus of claim 1, wherein the separation grid comprises a plurality of holes operable to allow passage of neutral particles generated in a plasma to the processing chamber.

8. The plasma processing apparatus of claim 7, wherein the separation grid is operable to filter one or more ions generated in the plasma.

9. The plasma processing system of claim 1, wherein the apparatus comprises a gas injection port operable to inject a process gas adjacent to the vertical surface of the dielectric sidewall.

10. A plasma processing apparatus, comprising:
a processing chamber;
a plasma chamber, the plasma chamber comprising a dielectric sidewall;
a separation grid positioned between the processing chamber and the plasma chamber along a vertical direction;
wherein the dielectric sidewall comprises a first portion and a second portion, the second portion of the dielectric sidewall being adjacent to the separation grid, the second portion flaring from the first portion of the dielectric sidewall;
wherein the apparatus comprises a first induction coil positioned about the first portion of the dielectric sidewall, the apparatus comprising a second induction coil positioned adjacent to the second portion of the dielectric sidewall.

11. The plasma processing system of claim 10, wherein the plasma chamber has a width along a horizontal direction, the width of the plasma chamber at the second portion of the dielectric sidewall being greater than the width of the plasma chamber at the first portion of the dielectric sidewall.

12. The plasma processing system of claim 10, further comprising a grounded Faraday shield positioned between the first induction coil and the first portion of the dielectric sidewall and between the second induction coil and the second portion of the dielectric sidewall.

13. The plasma processing apparatus of claim 10, wherein the grounded Faraday shield is a unitary structure.

14. The plasma processing apparatus of claim 13, wherein a density of spaces in the grounded Faraday shield adjacent the first portion of the dielectric sidewall is different than a density of spaces of the grounded Faraday shield adjacent the second portion of the dielectric sidewall.

15. The plasma processing apparatus of claim 10, wherein the apparatus comprises a gas injection insert disposed within the plasma chamber.

16. The plasma processing apparatus of claim 10, wherein the apparatus comprises a gas injection port operable to inject a process gas adjacent to the vertical surface of the dielectric sidewall.

17. A method for processing a workpiece, comprising:
placing the workpiece in a processing chamber, the processing chamber being separated from a plasma chamber by a separation grid along a vertical direction;
providing a process gas into the plasma chamber via a gas injection port proximate a vertical surface of a dielectric sidewall;
energizing a first induction coil proximate the vertical surface of the dielectric sidewall with radio frequency energy;
energizing a second induction coil proximate the separation grid with radio frequency energy; and
flowing neutral particles generated in a plasma through the separation grid to the workpiece within the processing chamber.

18. The method of claim 17, wherein the second induction coil is located proximate the vertical surface of the dielectric sidewall.

19. The method of claim 17, wherein the dielectric sidewall comprises a first portion and a second portion, the second portion of the dielectric sidewall flaring from the first portion of the dielectric sidewall.

20. The method of claim 19, wherein the second induction coil is located proximate the second portion of the dielectric sidewall.
